(19) United States
(12) Patent Application Publication
(10) Pub. No.: US 2025/0204201 A1
(43) Pub. Date: Jun. 19, 2025

(54) TRENCH OVERHANG FOR SI-AP

(71) Applicant: Applied Materials, Inc., Santa Clara, CA (US)

(72) Inventors: Dieter HAAS, Santa Clara, CA (US); Jungmin LEE, Santa Clara, CA (US)

(21) Appl. No.: 18/972,076

(22) Filed: Dec. 6, 2024

Related U.S. Application Data
(60) Provisional application No. 63/607,816, filed on Dec. 8, 2023.

(51) Int. Cl. H10K 59/80; H10K 59/12; H10K 59/122; H10K 102/10

(52) U.S. Cl. CPC H10K 59/80515; H10K 59/1201; H10K 59/122; H10K 59/80517; H10K 59/873; H10K 2102/101

(57) ABSTRACT

In one or more embodiments, a sub-pixel circuit includes a first sub-pixel and a second sub-pixel. Each of the sub-pixels includes an anode structure. The anode structure includes an overhang defined by an extension of an upper portion of a sidewall of the anode structure extending past a lower portion of the sidewall of the anode structure. Each of the sub-pixels includes an organic light-emitting diode (OLED) material on an uppermost surface of the anode structure, a cathode disposed over the OLED material disposed on the anode structure, and an encapsulation layer disposed over the cathode. The sub-pixel circuit further includes a well disposed between and defined by adjacent anode structures of the first sub-pixel and the second sub-pixel. The encapsulation layer separates the OLED material and the cathode disposed over the uppermost surface of the anode structure from the OLED material and the cathode disposed in the well.

### CROSS-REFERENCE TO RELATED APPLICATIONS

This application claims benefit to U.S. Pat. Appl. No. 63/607,816, filed Dec. 8, 2023, which is herein incorporated by reference in its entirety.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago. Accordingly, what is needed in the art are sub-pixel circuits and methods of forming sub-pixel circuits to increase pixel-per-inch and provide improved OLED performance.

### SUMMARY

In one or more embodiments, a sub-pixel circuit includes a first sub-pixel and a second sub-pixel. Each of the first sub-pixel and the second sub-pixel includes an anode structure. The anode structure includes an overhang defined by an extension of an upper portion of a sidewall of the anode structure extending past a lower portion of the sidewall of the anode structure. Each of the first sub-pixel and second sub-pixel also includes an organic light-emitting diode (OLED) material on an uppermost surface of the anode structure, a cathode disposed over the OLED material disposed on the anode structure, and an encapsulation layer disposed over the cathode. The sub-pixel circuit further includes a well disposed between the first sub-pixel and the second sub-pixel defined by adjacent anode structures of the first sub-pixel and the second sub-pixel. The encapsulation layer separates the OLED material and the cathode disposed over the uppermost surface of the anode structure from the OLED material and the cathode disposed in the well.

In one or more embodiments, a sub-pixel circuit includes a first sub-pixel and a second sub-pixel. Each of the first sub-pixel and the second sub-pixel includes an anode structure. The anode structure includes two or more layers having different compositions. The anode structure includes an overhang defined by an extension of an upper portion of a sidewall of the anode structure extending past a lower portion of the sidewall of the anode structure. Each of the first sub-pixel and second sub-pixel also includes an organic light-emitting diode (OLED) material on an uppermost surface of the anode structure, a cathode disposed over the OLED material disposed on the anode structure, and an encapsulation layer disposed over the cathode. The sub-pixel circuit further includes a well disposed between the first sub-pixel and the second sub-pixel defined by adjacent anode structures of the first sub-pixel and the second sub-pixel. The encapsulation layer separates the OLED material and the cathode disposed over the uppermost surface of the anode structure from the OLED material and the cathode disposed in the well.

In one or more embodiments, a method of forming a sub-pixel circuit includes forming at least two anode structures. Each anode structure includes an overhang defined by an extension of an upper portion of a sidewall of each anode structure extending past a lower portion of the sidewall of each anode structure. The method further includes depositing an organic light-emitting diode (OLED) material, a cathode, and an encapsulation layer corresponding to a first sub-pixel. The encapsulation layer separates the OLED material and the cathode deposited over an uppermost surface of each anode structure from the OLED material and the cathode disposed in a well defined by adjacent anode structures of the first sub-pixel and a second sub-pixel.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit on an x-axis according to embodiments described herein.

FIG. 1B is a schematic cross-sectional view of the sub-pixel circuit on y-axis according to embodiments described herein.

FIG. 1C is a schematic, top view of a sub-pixel circuit according to embodiments described herein.

FIG. 2 is a flow diagram of a method for forming a sub-pixel according to embodiments described herein.

FIGS. 3A-3J are schematic, cross-sectional views of a substrate on an x-axis during a method of forming a sub-pixel circuit according to embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In various embodiments, the sub-pixels employ advanced anode structures to improve functionality of the display.

Each of the embodiments described herein of the sub-pixel circuit include a plurality of sub-pixels with each with adjacent anode structures that are permanent to the sub-pixel circuit. While the Figures depict two sub-pixels or three sub-pixels with each sub-pixel, the sub-pixel circuit of the embodiments described herein include a plurality of sub-pixels, such as two or more sub-pixels. Each sub-pixel has OLED materials configured to emit a white, red, green, blue, or other color light when energized. For example, the OLED materials of a first sub-pixel emit a red light when energized, the OLED materials of a second sub-pixel emit a green light when energized, and the OLED materials of a third sub-pixel emit a blue light when energized.

The anode structures with overhangs are permanent to the sub-pixel circuit. The overhangs provide for formation of the sub-pixel circuit using evaporation deposition and provide for separation of the OLED material and the cathode between each sub-pixel circuit. The break of the OLED material and the cathode by the encapsulation layer allows current to flow individually to the sub-pixels. Evaporation deposition is utilized for deposition of OLED materials (including a hole injection layer (HIL), a hole transport layer (HTL), an emissive layer (EML), and an electron transport layer (ETL)) and cathode. In some instances, an encapsulation layer may be disposed via evaporation deposition. The overhangs and the evaporation angle set by the evaporation source define the deposition angles, i.e., the overhangs provide for a shadowing effect during evaporation deposition with the evaporation angle set by the evaporation source. In order to deposit at a particular angle, the evaporation source is configured to emit the deposition material at a particular angle with regard to the overhangs.

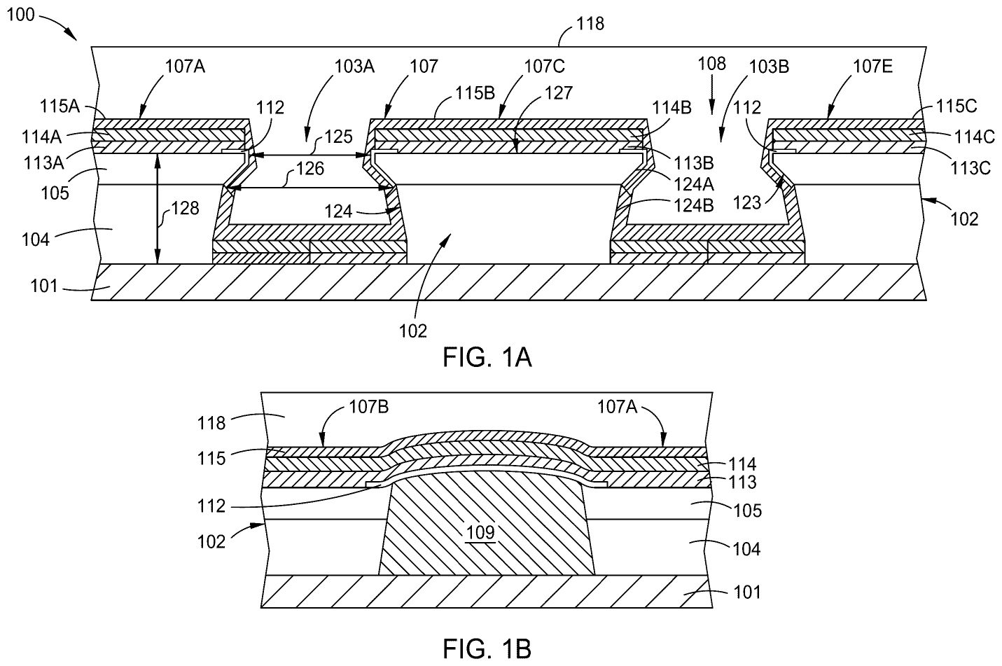

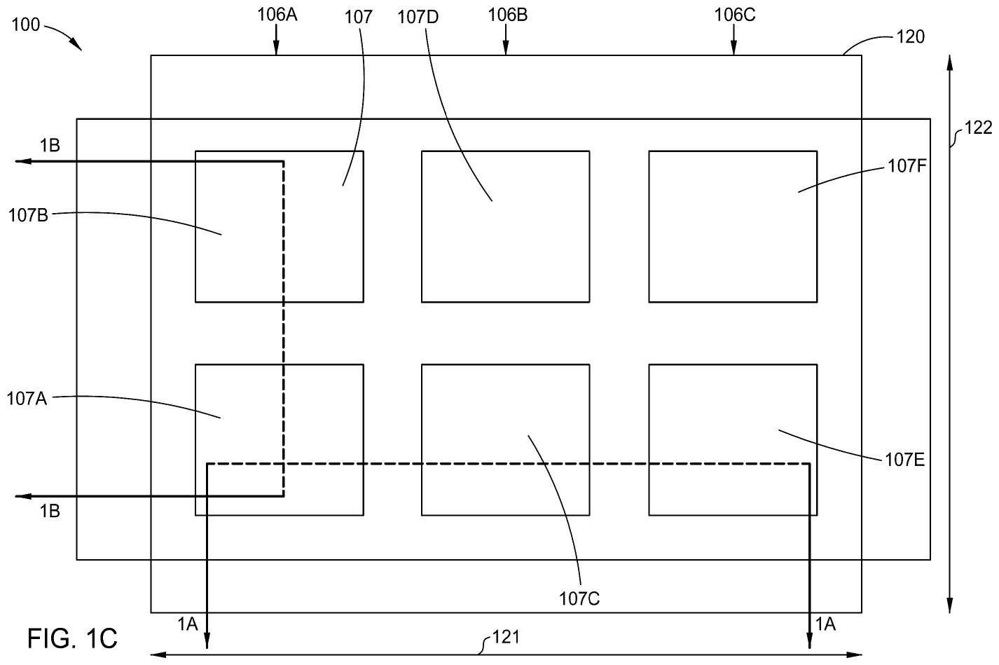

FIG. 1A is a schematic, cross-sectional view of a sub-pixel circuit 100 on an x-axis 121, according to one or more embodiments. The cross-sectional view of FIG. 1A is taken along section line 1A-1A of FIG. 1C. FIG. 1B is a schematic, cross-sectional view of a sub-pixel circuit 100 on a y-axis 122, according to one or more embodiments. The cross-sectional view of FIG. 1B is taken along section line 1B-1B of FIG. 1C. FIG. 1C is a schematic, top view of a sub-pixel circuit 100. The sub-pixel circuit 100 includes a substrate 101. The substrate 101 may be a backplane. The backplane includes, but is not limited to, a complementary metal-oxide-semiconductor (CMOS) array, a thin-film transistor (TFT) array, or a glass backplane.

A plurality of anode structures 102 are disposed over the substrate 101. The plurality of anode structures 102 disposed over the substrate 101 may be disposed on the substrate 101. Adjacent anode structures 102 define wells 103 therebetween. Each anode structure 102 has an overhang 123 defined by an extension of an upper portion 124A of a sidewall 124 of the anode structure 102 extending past a lower portion 124B of the sidewall 124 of the anode structure 102. The anode structures 102 include a metal-containing material. The metal-containing material includes, but is not limited to, a transparent conductive oxide (TCO), copper, titanium, aluminum, molybdenum, silver, chromium, or combinations thereof. The TCO material includes, but is not limited to, indium zinc oxide (IZO), indium tin oxide (ITO), indium gallium zinc oxide (IGZO), or combinations thereof.

The anode structures 102 may include two or more layers. The two or more layers include a second layer 105 disposed on a first layer 104. The second layer 105 includes the upper portion 124A of a sidewall 124. The first layer 104 includes the lower portion 124B of the sidewall 124. In some embodiments, the first layer 104 and the second layer 105 include different compositions.

A well 103 is defined by adjacent anode structures 102. The well 103 has a first width 125 between the adjacent extensions of the overhangs 123 of the adjacent anode structures 102. The well 103 has a second width 126 between adjacent anode structures 102 where the upper portion 124A and the lower portion 124B meet. The difference between the second width 126 and the first width 125 is 50 nm or greater. The height 128 is 200 nm or greater.

The sub-pixel circuit 100 has a plurality of sub-pixel lines (e.g., a first sub-pixel line 106A, a second sub-pixel line 106B, and a third sub-pixel line 106C). The sub-pixel lines are adjacent to each other along the x-axis 121. Each sub-pixel line includes at least two sub-pixels 107. For example, the first sub-pixel line 106A includes a first sub-pixel 107A and a second sub-pixel 107B, the second sub-pixel line 106B includes a third sub-pixel 107C and a fourth sub-pixel 107D, and the third sub-pixel line 106C includes a fifth sub-pixel 107E and a sixth sub-pixel 107F. The first sub-pixel 107A and the second sub-pixel 107B are aligned along the y-axis 122. The first sub-pixel 107A, the third sub-pixel 107C, and the fifth sub-pixel 107E are aligned in the x-axis 121. While FIG. 1A depicts a first sub-pixel line 107A, a second sub-pixel line 107B, and a third sub-pixel line 107C, the sub-pixel circuit 100 of the embodiments described herein may contain additional sub-pixel lines such as a fourth sub-pixel line.

Each sub-pixel line has OLED materials configured to emit a white, red, green, blue, or other color light when energized. In some embodiments, the OLED materials of the first sub-pixel line 106A emit a red light when energized, the OLED materials of the second sub-pixel line 106B emit a green light when energized, the OLED materials of the third sub-pixel line 106C emit a blue light when energized, and the OLED materials of a fourth sub-pixel emit another color light when energized. The OLED materials within a sub-pixel line may be configured to emit the same color light when energized. In some embodiments, the OLED materials of the first sub-pixel 107A and the second sub-pixel 107B of the first sub-pixel line 106A emit a red light when energized and the OLED materials of the third sub-pixel 107C and the fourth sub-pixel 107D of the second sub-pixel line 106B emit a green light when energized.

Adjacent sub-pixel lines are divided by an opening 108 of a well 103 that extends along the y-axis 122 in between the anode structures 102 of adjacent sub-pixel lines. For example, FIG. 1A illustrates a sub-pixel circuit 100 including a first well 103A and a second well 103B. The first well 103A is defined by the anode structures 102 of the first sub-pixel 107A and the second sub-pixel 107B of the first sub-pixel line 106A, and the anode structures 102 of the third sub-pixel 107C and the fourth sub-pixel 107D of the second sub-pixel line 106B. The opening 108 of the first well 103A divides the first sub-pixel line 106A and the second sub-pixel line 106B. The second well 103B is defined by the anode structures 102 of the third sub-pixel 107C and the fourth sub-pixel 107D of the second sub-pixel line 106B, and the anode structures 102 of the fifth sub-pixel 107E and the sixth sub-pixel 107F of the third sub-pixel line 106C. The opening 108 of the second well 103B divides the second sub-pixel line 106B and the third sub-pixel line 106C.

A passivation layer 112 is disposed on an uppermost surface 127 and an upper portion 124A of each anode structure 102. In some embodiments, the passivation layer 112 is disposed along the entire sidewall 124 of the anode structure 102. In some embodiments, the passivation layer 112 is disposed in the well 103.

An OLED material 113 and a cathode 114 are disposed over the anode structures 102. The OLED material 113 may include one or more of a hole injection layer (HIL), a hole transport layer (HTL), an emissive layer (EML), and an electron transport layer (ETL). The OLED material 113 is disposed over and in contact with the uppermost surface of the anode structure 102. The OLED material 113 used in each sub-pixel 107 may vary to alter the light that will emit when the sub-pixel 107 is energized. The OLED material 113 is disposed within at least a portion of the well 103 not shadowed by the overhangs 123 of the anode structures 102. Additionally, the OLED material 113 may be disposed on the sidewall 124 of the anode structure 102.

In some embodiments, the cathode 114 is disposed on the OLED material 113. The cathode 114 may also be disposed on the sidewall 124 of the anode structure 102. The cathode 114 may also be disposed within at least a portion of the well 103 not shadowed by the overhangs of the anode structures 102. The cathode 114 includes a conductive material, such as a metal. In some embodiments, the cathode 114 includes, but is not limited to, silver, magnesium, chromium, titanium, aluminum, ITO, or a combination thereof. In one or more embodiments, the material of the cathode 114 is different from the material of the anode structure 102. In some embodiments, an encapsulation layer 115 is disposed over the OLED material 113 and the cathode 114. The encapsulation layer 115 is disposed within the well 103. In some embodiments, the encapsulation layer 115 directly contacts the passivation layer 112 disposed on the sidewall 124 of the anode structure 102. In some embodiments, the encapsulation layer 115 directly contacts the sidewall 124 of the anode structure 102. Accordingly, two different encapsulation layers 115 may be disposed in the well 103. The encapsulation layer 115 may be made of any suitable material, including a non-conductive inorganic material, such as a silicon-containing material. The silicon-containing material may include Si₃N₄ containing materials.

There may also be a global encapsulation layer 118 disposed over the substrate 101. The global encapsulation layer 118 extends over the cathode 114 disposed over the anode structure 102 and extends into the well 103. The global encapsulation layer 118 may also contact the sidewalls 124 of the anode structure 102. The global encapsulation layer 118 may be made of any suitable material, including a non-conductive inorganic material, such as a silicon-containing material. The silicon-containing material may include Si₃N₄ containing materials. In one or more embodiments, the global encapsulation layer 118 is disposed over the encapsulation layer 115.

The overhang 123 of the anode structure 102 allows the encapsulation layer 115 to separate the OLED material 113 and the cathode 114 over the uppermost surface 127 of the anode structure 102 from the OLED material 113 and the cathode 114 disposed in each well 103. The break of the OLED material 113 and the cathode 114 by the encapsulation layer 115 allows current to flow individually to the sub-pixels 107.

A gap-fill material 109 is disposed between adjacent anode structures 102 within the same sub-pixel line. For example, a gap-fill material 109 is disposed between the first sub-pixel 107A and the second sub-pixel 107B. The gap filling may be made of any suitable material. In one or more embodiments, the gap filling is made of a non-conductive material that can be flattened by a chemical mechanical polishing (CMP) process. The non-conductive material may include a silicon nitride, silicon, or silicon oxide.

The passivation layer 112, OLED material 113, and cathode 114 are disposed over the gap-fill material 109. In some embodiments, the passivation layer 112, OLED material 113, and cathode 114 are disposed across the entire well 103 contacting the anode structures 102 of each sub-pixel forming the well 103. In some embodiments, the encapsulation layer 115 is disposed over the gap-fill material 109. Further, in some embodiments, the encapsulation layer 115 is disposed across the entire well 103 contacting the anode structures 102 of each sub-pixel 107 forming the well 103 within the same sub-pixel line.

FIG. 1C is a schematic, top view of a sub-pixel circuit 100, according to embodiments. It should be understood that FIG. 1C does not include the OLED material, the cathode 114, the encapsulation layer 115, or the global encapsulation layer 118 for illustrative purposes. One or more busbars 120 are disposed adjacent to the substrate 101. The busbars 120 provide a current to the sub-pixel circuit 100. Although FIG. 1C depicts the sub-pixel circuit 100 including four busbars 120, it is contemplated that any number of busbars can be used, including but not limited to one busbar, two busbars, three busbars, or six busbars.

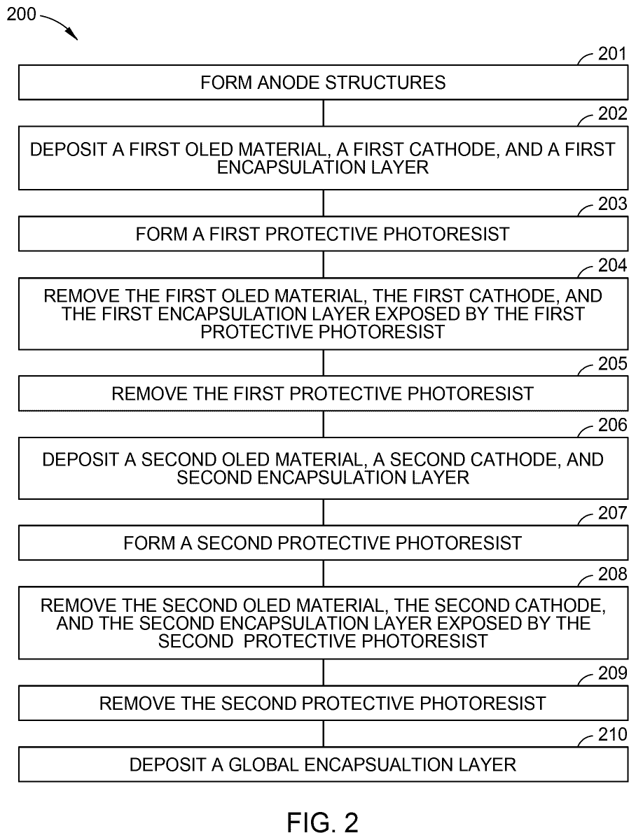

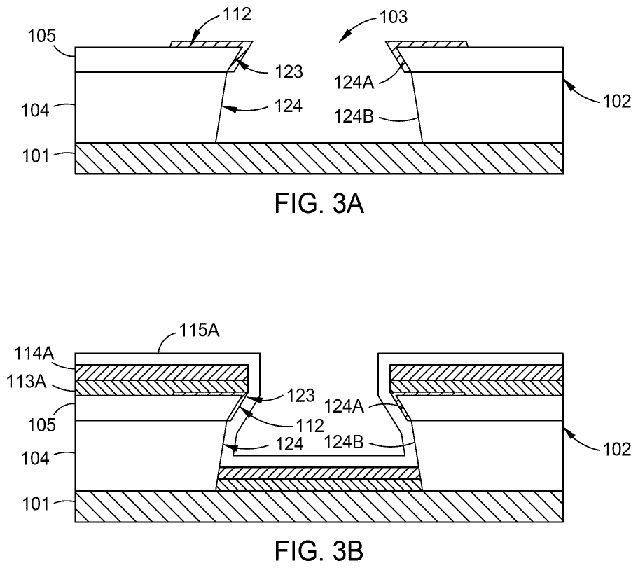

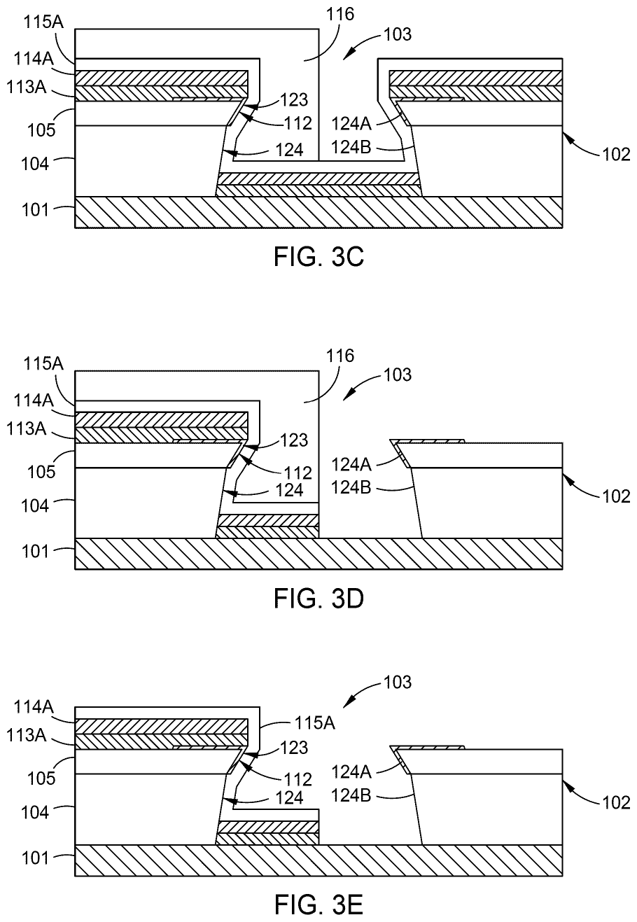

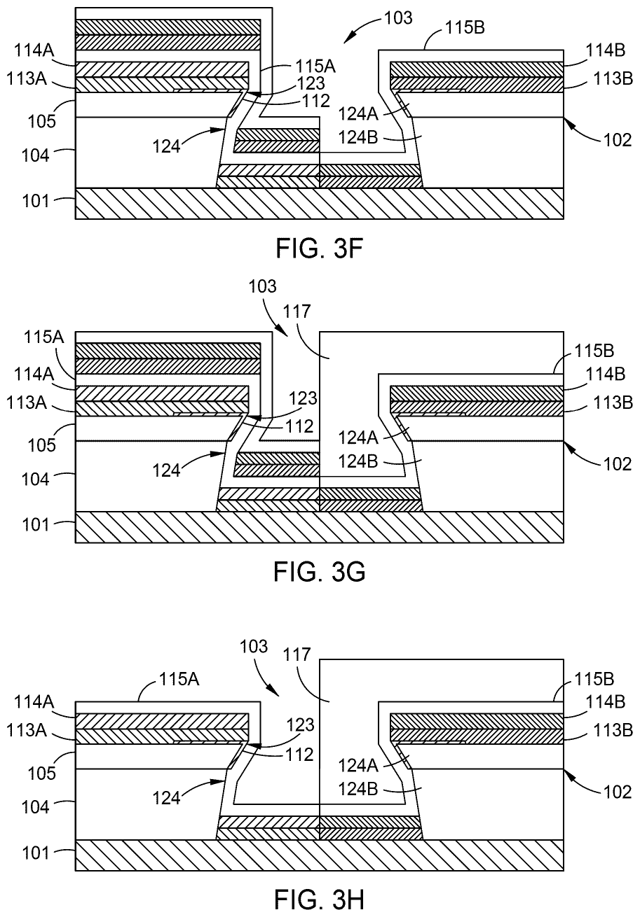

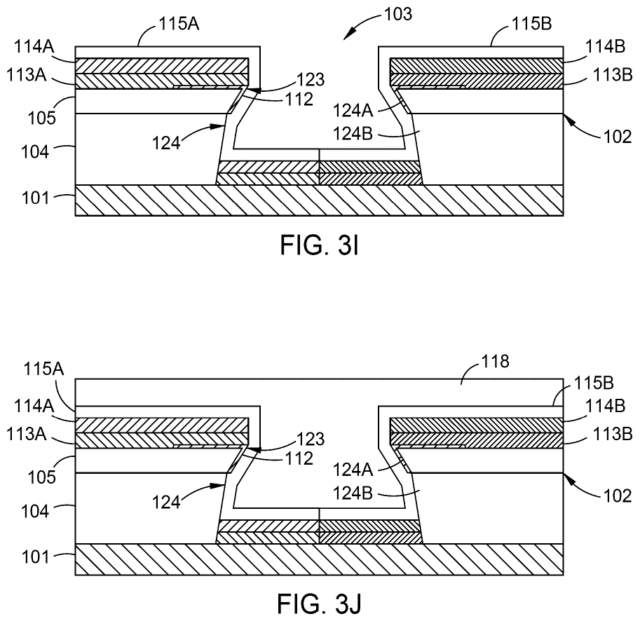

FIG. 2 is a flow diagram of a method 200 for forming a sub-pixel circuit 100. FIGS. 3A-3J are schematic, cross-sectional views of a substrate on an x-axis 121 during a method of forming a sub-pixel circuit 100 according to embodiments described herein. It should be understood that although FIGS. 3A-3J depict a substrate 101 with two anode structures 102, method 200 can be performed on a substrate 101 with any number of anode structures 102.

At operation 201, as shown in FIG. 3A (along the x-axis 121), anode structures 102 are formed. To form the anode structures 102, at least one anode layer is deposited. The depositing the at least one anode layer may include depositing a first layer 104 and a second layer 105 over the substrate 101. A photoresist material is disposed over the at least one anode layer. The photoresist material is exposed to a lithography process such that a patterned photoresist exposes an area corresponding to a well 103. An etching process removes portions of the one or more anode layers that are exposed. Removing the exposed portions forms the anode structure 102. The patterned photoresist is then removed. The passivation layer 112 is formed by deposition of a passivation material over the substrate 101. The passivation material may be patterned by a lithography process that exposes portions of the passivation material to be removed by an etching process.

At operation 202, as shown in FIG. 3B (along the x-axis 121), a first OLED material 113A, a first cathode 114A, and a first encapsulation layer 115A are deposited. The shadowing of the overhang 123 within the well 103 provides for an electrical break in the first OLED material 113A and the first cathode 114A disposed over the uppermost surface 127 of the anode structure 102 and a portion of the first OLED material 113A and the first cathode 114A disposed in the well 103. The first OLED material 113A and the first cathode 114A maintain continuity along the y-axis 122. For example, the first OLED material 113A and the first cathode 114A are disposed over the gap-fill material 109 across the well 103 between anode structures 102.

At operation 203, as shown in FIG. 3C (along the x-axis 121), a first protective photoresist 116 is formed. The first protective photoresist 116 if formed over the first sub-pixel line 106A and a first half of the well 103. The first protective photoresist 116 exposes a second half of the well 103 and the anode structure 102 of the second sub-pixel line 106B to be formed.

At operation 204, as shown in FIG. 3D (along the x-axis 121), the first OLED material 113A, the first cathode 114A, and the first encapsulation layer 115A exposed by the first protective photoresist 116 are removed. The first OLED material 113A, the first cathode 114A, and the first encapsulation layer 115A may be removed by one or more etch processes. At operation 205, as shown in FIG. 3E, the first protective photoresist 116 is removed.

At operation 206, as shown in FIG. 3F (along the x-axis 121), a second OLED material 113B, a second cathode 114B, and a second encapsulation layer 115B are deposited. The shadowing of the overhang 123 within the well 103 provides for an electrical break in the second OLED material 113B and the second cathode 114B disposed over the uppermost surface 127 of the anode structure 102 and a portion of the second OLED material 113B and the second cathode 114B disposed in the well 103. The second OLED material 113B and the second cathode 114B maintain continuity along the y-axis 122. For example, the second OLED material 113B and the second cathode 114B are disposed over the gap-fill material 109 across the well 103 between anode structures 102.

At operation 207, as shown in FIG. 3G (along the x-axis 121), a second protective photoresist 117 formed. The second protective photoresist 117 is over the anode structure 102 and a second half of the well 103. The second protective photoresist 117 exposes the first half of the well 103 and the anode structure 102 of the first sub-pixel line 106A. At operation 208, as shown in FIG. 3H (along the x-axis 121), the second OLED material 113B, the second cathode 114B, and the second encapsulation layer 115B exposed by the second protective photoresist 117 are removed. After the etching process is completed, at operation 209, as shown in FIG. 31 (along the x-axis 121), the second protective photoresist 117 is removed.

In some embodiments, operations 206-209 may be repeated to create the desired number of sub-pixels 107 that will each emit a different light. In some embodiments, the process is repeated one more time to create a total of three sub-pixels 107 in the sub-pixel circuit 100. In this embodiment, the first OLED material 113A may emit red light when energized, the second OLED material 113B may emit green light when energized, and the third OLED material 113C may emit blue light when energized.

At operation 210, as shown in FIG. 3J (along the x-axis 121), a global encapsulation layer 118 is deposited. The global encapsulation layer 118 is deposited over all sub-pixel lines 106A, 106B, and 106C. Benefits of the present disclosure include increased pixels-per-inch, decreased current leakage, increased device performance, increased device image resolution, decreased cost, and decreased maintenance. It is contemplated that one or more aspects disclosed herein may be combined. As an example, one or more aspects, features, components, operations and/or properties of the sub-pixel circuit 100, the substrate 101, the anode structure 102, the gap-fill material 109, the passivation layer 112, the OLED material 113, the cathode 114, the encapsulation layer 115, the global encapsulation layer 118, the wells 103, the sub-pixel lines 106A, 106B, 106C, the sub-pixels 107A, 107B, 107C, 107D, 107E, 107F, the busbars 120, and/or method 200 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A sub-pixel circuit, comprising:
a first sub-pixel and a second sub-pixel, each of the first sub-pixel and the second sub-pixel comprise:
an anode structure, the anode structure having an overhang defined by an extension of an upper portion of a sidewall of the anode structure extending past a lower portion of the sidewall of the anode structure;
an organic light-emitting diode (OLED) material on an uppermost surface of the anode structure;
a cathode disposed over the OLED material disposed on the anode structure; and
an encapsulation layer disposed over the cathode; and
a well disposed between the first sub-pixel and the second sub-pixel defined by adjacent anode structures of the first sub-pixel and the second sub-pixel, wherein the encapsulation layer separates the OLED material and the cathode disposed over the uppermost surface of the anode structure from the OLED material and the cathode disposed in the well.

2. The sub-pixel circuit of claim 1, wherein the anode structure comprises a metal-containing material.

3. The sub-pixel circuit of claim 2, wherein the metal-containing material comprises a transparent conductive oxide (TCO), copper, titanium, aluminum, molybdenum, silver, chromium, or combinations thereof.

4. The sub-pixel circuit of claim 3, wherein the TCO material includes indium zinc oxide (IZO), indium tin oxide (ITO), indium gallium zinc oxide (IGZO), or combinations thereof.

5. The sub-pixel circuit of claim 1, wherein the anode structure comprises a first layer and a second layer, the second layer is disposed on the first layer.

6. The sub-pixel circuit of claim 5, wherein the first layer and the second layer include different compositions.

7. The sub-pixel circuit of claim 1, wherein the encapsulation layer directly contacts the sidewall of the anode structure to separate the OLED material and the cathode disposed over the uppermost surface of the anode structure from the OLED material and the cathode disposed in the well.

8. The sub-pixel circuit of claim 1, wherein the encapsulation layer directly contacts a passivation layer disposed on the sidewall of the anode structure to separate the OLED material and the cathode disposed over the uppermost surface of the anode structure from the OLED material and the cathode disposed in the well.

9. The sub-pixel circuit of claim 1, wherein a passivation layer is disposed on the uppermost surface of the anode structure and the upper portion of the sidewall.

10. A sub-pixel circuit, comprising:
a first sub-pixel and a second sub-pixel, each of the first sub-pixel and the second sub-pixel comprise:
an anode structure having two or more layers having different compositions, the anode structure having an overhang defined by an extension of an upper portion of a sidewall of the anode structure extending past a lower portion of the sidewall of the anode structure;
an organic light-emitting diode (OLED) material on an uppermost surface of the anode structure;
a cathode disposed over the OLED material disposed on the anode structure; and
an encapsulation layer disposed over the cathode; and
a well disposed between the first sub-pixel and the second sub-pixel defined by adjacent anode structures of the first sub-pixel and the second sub-pixel, wherein the encapsulation layer separates the OLED material and the cathode disposed over the uppermost surface of the anode structure from the OLED material and the cathode disposed in the well.

11. The sub-pixel circuit of claim 10, wherein the anode structure comprises a metal-containing material.

12. The sub-pixel circuit of claim 11, wherein the metal-containing material comprises a transparent conductive oxide (TCO), copper, titanium, aluminum, molybdenum, silver, chromium, or combinations thereof.

13. The sub-pixel circuit of claim 12, wherein the TCO material includes indium zinc oxide (IZO), indium tin oxide (ITO), indium gallium zinc oxide (IGZO), or combinations thereof.

14. The sub-pixel circuit of claim 10, wherein the encapsulation layer directly contacts the sidewall of the anode structure to separate the OLED material and the cathode over the uppermost surface of the anode structure from the OLED material and the cathode disposed in the well.

15. The sub-pixel circuit of claim 10, wherein the encapsulation layer directly contacts a passivation layer disposed on the sidewall of the anode structure to separate the OLED material and the cathode disposed over the uppermost surface of the anode structure from the OLED material and the cathode disposed in the well.

16. The sub-pixel circuit of claim 10, wherein a passivation layer is disposed on the uppermost surface of the anode structure and the upper portion of the sidewall.

17. The sub-pixel circuit of claim 10, wherein the OLED material of the first sub-pixel emits a light of a first color when energized and the second sub-pixel emits a light of a second color when energized.

18. A method, comprising:
forming at least two anode structures, each anode structure having an overhang defined by an extension of an upper portion of a sidewall of each anode structure extending past a lower portion of the sidewall of each anode structure;
depositing an organic light-emitting diode (OLED) material and a cathode corresponding to a first sub-pixel; and
depositing an encapsulation layer, the encapsulation layer separating the OLED material and the cathode deposited over an uppermost surface of each anode structure from the OLED material and the cathode disposed in a well defined by adjacent anode structures of the first sub-pixel and a second sub-pixel.

19. The method of claim 18, wherein the anode structures comprise a metal-containing material.

20. The method of claim 19, wherein the metal-containing material comprises a transparent conductive oxide (TCO), copper, titanium, aluminum, molybdenum, silver, chromium, or combinations thereof, wherein the TCO material includes, but is not limited to, indium zinc oxide (IZO), indium tin oxide (ITO), indium gallium zinc oxide (IGZO), or combinations thereof.
